(19) United States
(12) Patent Application Publication
(10) Pub. No.: US 2025/0240905 A1
(43) Pub. Date: Jul. 24, 2025

(54) SUPPORT STRUCTURE WITH IMPROVED ALIGNMENT FOR FRAMES OF A TILED DISPLAY WALL

(71) Applicants: BARCO N.V., Kortrijk (BE); BARCO CONTROL ROOMS GMBH, Karlsruhe (DE)

(72) Inventors: Roland Michael SCHMUKER, Karlsruhe (DE); Martin Christian Philipp EIGEL, Stutensee (DE); Georg Josef GIMBLER, Ettlingen (DE); Karim MEERSMAN, Kortemark (BE); Tom Gerard DECLERCK, Meulebeke (BE)

(73) Assignees: BARCO N.V., Kortrijk (BE); BARCO CONTROL ROOMS GMBH, Karlsruhe (DE)

(21) Appl. No.: 18/702,111

(22) PCT Filed: Oct. 17, 2022
(86) PCT No.: PCT/EP2022/078798

§ 371 Date: Apr. 17, 2024

(30) Foreign Application Priority Data
Oct. 18, 2021 (LU) 500750

(51) Int. Cl. H05K 5/30; A47B 81/06

(52) U.S. Cl. CPC H05K 5/30; A47B 81/062; A47B 81/064

(57) ABSTRACT

A kit for aligning and fixing within a first tolerance range a support structure for a tiled display wall. The support structure comprises a plurality of channel profiles arranged vertically, and a plurality of frame assemblies configured to be arranged in a first row of frames. The kit further comprises a plurality of bottom supports to be aligned within a second tolerance range larger than the first tolerance range, and configured to be fixed to the channel profiles, a plurality of top supports configured to be fixed to the channel profiles, and supporting means comprising a plurality of spring loaded suspension blocks configured to be attached to the bottom supports, such that, when the frame assemblies are laid on the supporting means, the supporting means support the frame assemblies while aligning and fixing the frame assemblies, within the first tolerance range, to the top supports.

### TECHNICAL FIELD

The present disclosure relates to the field of kits for aligning and fixing a support structure for frames of a tiled display wall, a support structure for a tiled display wall, and a method of aligning and fixing a support structure for a tiled display wall.

### BACKGROUND

The installation of a tiled display wall consisting of a plurality of display modules requires a good starting condition. This means that the base of the installation, provided by the support or initial fixation to a wall, floor or rack must form a rigid and straight line or reference plane. This is required because any deformation or deviation from this straight line or reference plane will lead to deformations in the screen surface in all X/Y directions (in the screen plane) or Z direction (perpendicular to the screen plane).

These deformations lead to optical defects such as seams (pixels distance inconsistencies) or steps (pixels popping out of the display plane or abrupt changes) and waves (waveform deformation through the display plane, continuous transient without abrupt changes) and result in the misalignment of tiled display walls.

The problem of the alignment of tiled display walls is well known in the art. WO2019034786 describes a support substructure for fastening a display tile to a support structure of a tile display with an alignment mechanism. WO2013192614 describes a mounting system for adjusting the alignment of individual displays for display arrays. U.S. Pat. No. 8,194,385 describes a precision alignment system for modular frames as a mounting structure for LED panels. US20190191574 describes a display panel mounting structure for a tiled display device capable of aligning a display panel with the adjacent display panels. While these disclosures describe different means for the alignment of display tiles, the alignment of the support structure itself, creating and containing an initial good starting condition, is key to provide a perfectly aligned display wall. During the installation of the display wall, no deformation or change impact to this starting condition should occur.

Current installation methods and concepts are often subject to inaccurate positioning of wall mountings, inaccurate support bases or deformation during build up.

The use of laser beams and standard spirit levels leaves room for interpretation because of the thickness of the laser beam or the inaccurate position of the air bubble between the two markers of a spirit level. With a digital spirit level, the number of digits one tolerates is also bound to interpretation.

Solving these inaccuracies leads often to time consuming alignment methods (iterative actions) or expensive tools and installation aids (theodolites or sensing equipment).

These complex tools also require high level skilled people.

In addition, it is practically impossible to drill in concrete and mount support frames with bolts resulting in an end accuracy of 0.1 mm. This contradicts the above described issue that the starting condition needs to be very accurate to exclude deformations.

EP2116986 describes a structural support which is connected to interconnected display tiles trough attachment members which may be deformable in any direction with respect to the structural support to ensure that the inaccurate alignment of the structural support does not compromise the alignment of the display tiles. Such deformable attachment members may negatively impact the mechanical stability against for example wind, weather, and vibrations of the display wall.

There is thus a need for improvement in the art.

### SUMMARY

Aspects of the present disclosure relate to a kit for aligning and fixing within a first tolerance range a support structure for a tiled display wall composed of a plurality of display modules. The support structure comprises a plurality of channel profiles configured to be arranged vertically and fixed to a wall or a structure. The support structure also comprises a plurality of frame assemblies comprising at least one frame, wherein each frame is configured to receive at least one display module, and each frame has an edge, the plurality of frame assemblies are configured to be arranged in a first row of frames. The kit comprises a plurality of bottom supports configured to be aligned within a second tolerance range larger than the first tolerance range and configured to be mounted on the channel profiles. The kit also comprises a plurality of top supports configured to be mounted on the channel profiles. The kit comprises supporting means comprising a plurality of spring loaded suspension blocks configured to be attached to the bottom supports, such that, when the frame assemblies are laid on the supporting means, the supporting means receives the edges of the first row of frames and supports the frame assemblies while aligning and fixing the frame assemblies, within the first tolerance range, to the top supports.

It is important to provide a stable configuration upon the installation of a support structure. With the kit defined above, the time to install and align the support structure, the number of iterations, and the number of adjustments are reduced to the minimum. Standard equipment is provided for the installation of the support structure but is used in a novel and inventive way, which provides the required alignment accuracy and reduces drastically the installation time.

The plurality of spring loaded suspension blocks can be compared with a matrix spring, supporting the weight of the structure very uniformly. The springs will compress more if the springs carry more weight. This results in the plurality of supporting means to provide a uniform supported base which forms a straight line, and thereby providing the required alignment accuracy while fixing the support structure to the channel profiles.

Preferably, the kit further comprising top fixation means provided in the top supports, the top fixation means further comprising means to adjust at least one of the horizontal, the vertical and the depth position of the upper portion of the first row of frames with respect to a reference plane.

While the support structure is being supported by the spring loaded suspension blocks, which also provide the vertical aligned position, the support structure can be fixed to the top fixation means. The alignment of the support structure with respect to a reference plane can then be made. In particular, the depth in the upper portion of the support structure can be adjusted.

It is an advantage that the top support comprise a top fixation point for fixing the upper portion of the first row of frames to the channel profiles.

Once the desired position has been reached, the upper portion of the first row of frames can be fixed to the channel profiles with fixing means provided in the top fixation means.

Preferably, the top fixation point is provided in a fixation frame comprising a slot, wherein the position of the top fixation point is configured to be adjusted within the frame.

The frame can provide an additional tolerance range while fixing the upper portion of the row of frames to the channel profiles.

Advantageously, the top fixation point is further configured to adjust the depth of the upper portion of the row of frames.

With the top fixation point, the depth but also the tilt of the first row of frames can be adjusted with respect to a reference plane.

Advantageously, the kit may further comprise bottom fixation means provided in the bottom supports, the bottom fixation means further comprising means to adjust at least one of the horizontal, the vertical and the depth position of the lower portion of the first row of frames with respect to a reference plane.

While being supported by the bottom supports or after fixation to the top supports, the support structure can be aligned with respect to a reference plane by further adjusting the bottom fixation means. Once the desired position is reached, it can be fixed by means of fixing means, such as precision bolts for example.

Preferably, the bottom fixation means comprise a bottom fixation point for fixing the bottom portion of the first row of frames to the channel profile.

Once the desired position is achieved, the position is fixed, and the first row of frames can be fixed in that position.

Advantageously, the bottom fixation point is provided in a fixation frame comprising a slot, wherein at least one of the position of the bottom fixation point is configured to be adjusted within the frame for fixing the horizontal and/or vertical position of the first row of frames and/or wherein the depth of the fixation point is configured to be adjusted for fixing the depth of the first row of frames.

Preferably, the supporting means are configured to be removable after installation of the support structure.

The spring loaded suspension blocks can be removed afterwards so the spring loaded suspension blocks do not protrude from the bottom of the screen and for example do not disturb the image emitted by the display.

It is preferred that the supporting means are coupled to the bottom supports, wherein the coupling mechanism is preferably a hooking mechanism.

A hooking mechanism is easy to implement. No fixing means such as screws or bolts are required. The supporting means can simply be unhooked and removed from the bottom fixation points once the installation is complete. Other temporary attaching means can be implemented, such as a magnetic attaching means for example. However, the strength of the magnets should be sufficient to carry the weight of the first row of frames.

It is preferred that the top support described hereinabove comprises a top fixation point for fixing the upper portion of the first row of frames to the channel profiles.

Such a fixation point is simple to implement.

Preferably, the top fixation point is provided in a fixation frame comprising a slot, wherein the position of the top fixation point is configured to be adjusted within the frame.

Providing a frame provides the possibility to further adjust the vertical and horizontal position.

More preferably, the top fixation point is further configured to adjust the depth of the upper portion of the row of frames.

It is important to provide simple means for adjusting the depth. Rotating the top fixation point can be implemented for adjusting the depth, and thereby adjust the tilt angle of the first row of frames.

It is preferred that the kit further comprises a rigid ruler comprising a spirit level, the rigid ruler being configured to mechanically transfer the orientation of an aligned upper or lower row of frames, and the spirit level being configured to provide a spirit level reference of an aligned upper or lower row of frames to align the row of frames with respect to the aligned upper or lower row of frames.

The rigid ruler can have a length corresponding to at least two rows of frames for example such that the orientation of a row be transferred to a second row mechanically. For the final adjustment, the spirit level of the rigid ruler can be used. Using the reference readings on the spirit level of the aligned row of frames removes room for interpretation errors. The subsequent row is automatically aligned with respect to the aligned row of frames. Interpretation factors are excluded, as the subsequent row of frames is aligned with respect to a reference provided by an aligned row of frames.

Preferably, the spirit level is an analog or digital spirit level.

Advantageously, the second tolerance range is [−10; +10] mm along the x and y directions and [−5; +5] mm in the z direction.

Such tolerance ranges are easy to be achieved with standard equipment.

Preferably, the first tolerance range is preferably ±0.1 mm, even more preferably ±0.05 mm, and even more preferably ±0.01 mm along the x, y and z directions.

Such a tolerance range results in a tiled display wherein misalignment errors are not visible by the user. The first tolerance range to be achieved depends on the pixel pitch and can thus vary with the type of display. The first tolerance range can be at most 5% of the pixel pitch to reduce visual artifacts.

It is an advantage that the display modules are active modules, such as at least one of display modules, LCD modules, OLED display modules.

The present invention can be applied to any type of display, such as active displays which comprises display elements or display modules which are to be aligned one with respect to the other, or with respect to a reference plane, on a support structure. Active means that the image is generated by the module itself, not by projection.

In another aspect there is also provided a support structure for a tiled display wall, the support structure comprising a plurality of channel profiles configured to be arranged vertically and fixed to a wall or a structure, a plurality of frame assemblies, wherein each frame is configured to receive at least one display module, the plurality of frame assemblies are configured to be arranged in a row of frames, and further comprising the kit defined above.

The channel profiles can be provided separately or in addition to the kit. Any type of channel profiles can be used.

Preferably, the frames are provided with horizontally slotted holes in the upper and/or lower portions for fixing the frames into the top and/or bottom supports.

The slotted holes provide additional tolerance when fixing the frames to the channel profiles, or more particularly to the top and bottom supports.

Even more preferably, the slotted holes are provided in the corners of the frames.

It is an advantage that individual frame assemblies are fixed to each other with connection plates provided along the edges.

The connection plates ensure a step at the edges between individual frame assemblies of less than 0.2 mm.

In another aspect, there is also provided a method for aligning and fixing within a first tolerance range a support structure for a tiled display wall, the method comprising the steps of installing a plurality of channel profiles vertically on a wall or structure, providing a plurality of bottom supports aligned within a second tolerance range larger than the first tolerance range, in the channel profiles, providing a plurality of top supports in the channel profiles, attaching supporting means comprising a plurality of spring loaded suspension blocks to the bottom supports, providing a plurality of frame assemblies to be arranged in a first row of frames, each frame having an edge and being configured to receive at least one display module, laying the frame assemblies on the supporting means, such that the supporting means receives the edges of the first row of frames and supports the frame assemblies, and aligning and fixing the frame assemblies to the top supports within the first tolerance range.

With this method, every frame assembly is supported by at least one spring loaded suspension block and is fixed to a vertical channel profile by a top support. With the spring loaded suspension blocks, the vertical position of the first row of frames is ensured while the first row of frames are being fixed and aligned within the first tolerance range, to the top supports.

The method helps to create and maintain a good starting condition without impacting time (no iterations), complexity (use of standard tools) and cost (no high level skills or accurate wall or site preparations needed) with the introduction of spring suspended base support (spring blocks) for uniform load distribution and support. When a mounting point is positioned slightly higher or lower due to e.g., drilling inaccuracy, bad drill hole marking, the spring mounted support will compensate for the deviating position while still supporting the frame in a uniform way. This results in a stress-free framework avoiding deformations.

Preferably, the method comprises the step of providing additional frame assemblies to compose the first row of frames and of connecting the frame assemblies together at their edges; preferably with connection plates.

Even more preferably, the top supports further comprise top fixation means, the top fixation means further comprising means to adjust at least one of the horizontal, the vertical and the depth position of the upper portion of the first row of frames with respect to a reference plane and wherein the method further comprises the step of fixing the upper portion of the frame assemblies to the top fixation means.

It is an advantage that the method further comprises the step of adjusting the depth of the upper portion of the first row of frames with the top fixation means.

The tilt angle and/or orientation of the row of frames is thereby also adjusted.

Preferably, the step of adjusting the depth is performed with a laser beam, or a laser curtain, or a laser grid.

Even more preferably, the bottom supports further comprise bottom fixation points, the bottom fixation points further comprising means to adjust at least one of the horizontal, the vertical and the depth position of the bottom portion of the first row of frames with respect to a reference plane and comprising the step of fixing the bottom portion of the frame assemblies to the bottom fixation points.

The method may further comprise the step of adjusting the depth of the bottom portion of the first row of frames with the bottom fixation points.

Preferably, the step of adjusting the depth is performed with at least one of a laser beam, or a laser curtain, or a laser grid.

Once the first row of frames is in the desired position, it can be fixed to the upper and bottom fixation points.

Advantageously, the method further comprises the step of removing the supporting means from the bottom supports.

Removing the bottom supports has the advantage that the bottom supports do not disturb the viewer.

Preferably, the step of providing a plurality of bottom and/or top supports aligned within a second tolerance range larger than the first tolerance range, in the channel profiles, is performed with at least one of a laser beam, a laser curtain, a laser grid, or a spirit level.

It is an advantage that the method further comprises the step of providing a second row of frames on or below the first row of frames.

Once the first row of frames is aligned and fixed to the channel profiles, the second row of frames can be installed. It is easier to provide the second row of frames on top of the first row of frames, however it is also possible to provide the second row below the first row. During alignment and installation, if the second row is installed under the first row, the second row can then be supported by bottom fixation points or bottom supports or be directly fixed to the first row with connection plates. Installing the second row on top of the first row has the advantage that the second row can be supported by the first row during the installation.

Even more preferably, the step of providing the second row of frames is performed by providing additional frame assemblies to compose the second row of frames and of connecting the frame assemblies together at their edges, preferably with connection plates.

It is an advantage that the step of connecting the second row of frames to the first row of frames is performed with connection plates.

As the first row is already in the desired position, the use of connection plates mechanically transfers the alignment of the first row to the second row. The tilt angle still needs to be adjusted. The second row of frames is easily aligned with respect to the first row of frames. This drastically reduces alignment errors. This also drastically facilitates the installation procedure.

Preferably, the method comprises the step of providing a plurality of top supports, for the second row of frames, in the channel profiles.

The top supports first fix the second row to the channel profiles and can be further used in a subsequent step for a finer alignment. The step of providing the top supports for the second row is similar to the step of providing the top supports for the first row.

Preferably, the step of adjusting the depth is performed by mechanically transferring the orientation of the aligned upper or lower row of frames to the second row of frames with a rigid ruler.

The top and/or bottom fixation points can be used during this fine alignment procedure to adjust the tilt angle of the second row of frames.

It is an advantage that said rigid ruler further comprises a spirit level, and the method further comprises the step of adjusting the orientation of the second row of frames by adjusting the readings of the spirit level to the readings of the spirit level for the aligned upper or lower row of frames.

Excluding interpretation of measurement tools indicators (laser beam thickness, position of spirit level air bubble between markers) with the use of a rigid ruler in combination with a (digital) spirit level, where it is not the absolute indication of the level that is used, but the change (bubble moves or digits change) in position or digits to indicate that the second row of frames is in line/plane or deviating from the reference line/plane defined by the first row of frames.

The rigid ruler helps to transfer the deviation in a very direct way and acts as a reference to mount the frames in a straight line/plane with respect to the already installed row below, acting as a reference.

Preferably, the second tolerance range is [−10; +10] mm along the x and y directions and [−5; +5] mm in the z direction.

Preferably, the first tolerance range is preferably ±0.1 mm, even more preferably ±0.05 mm, and even more preferably ±0.01 mm along the x, y and z directions.

It is an advantage that the display modules are active modules such as at least one of display modules, LCD modules, OLED display modules.

There is also provided a support structure mounted with the method defined above.

There is also provided a method of aligning a support structure for a tiled display wall with the kit defined above.

### BRIEF DESCRIPTION OF DRAWINGS

These and other features, aspects, and advantages of the apparatus, systems and methods of the present disclosure will become better understood from the following description, appended claims, and accompanying drawing wherein:

FIG. 1A is a schematic representation of channel profiles fixed to a wall of a support structure for a tiled display wall.

FIG. 1B is a schematic representation of the supporting means fixed to the channel profiles of the support structure.

FIG. 1C is a close-up view of the supporting means comprising a spring loaded suspension block.

FIG. 2A is a close-up view of another example of supporting means installed on a bottom support, fixed to the vertical channel profile.

FIG. 2B is a close-up of the bottom fixation point provided in the bottom support.

FIG. 2C is a close up view of the bottom fixation point.

FIG. 2D is a close up view of the supporting means and the hooking mechanism.

FIG. 3A is a schematic representation of the installation of a first row of frames.

FIG. 3B is a representation of the upper portion of the frames fixed to the top fixation points.

FIG. 4A is a schematic representation of the installation of a first row and second row of frames.

FIG. 4B illustrates the connection plates connecting adjacent frame assemblies.

FIG. 5 is a schematic representation of a first and second row of frames installed and aligned on the support structure.

FIG. 6A is a schematic representation of the front view of a support structure comprising spring loaded suspension blocks.

FIG. 6B is a schematic representation of the side view of a support structure comprising spring loaded suspension blocks.

FIG. 7A is a schematic representation of the front view of a support structure comprising pneumatic valve suspension blocks.

FIG. 7B is a schematic representation of the side view of a support structure comprising pneumatic spring loaded suspension blocks.

FIG. 8 is a block diagram illustrating the installation sequence of the support structure and first row of frames.

FIG. 9 is a schematic block diagram illustrating the installation sequence of the second row of frames.

### DESCRIPTION OF EMBODIMENTS

Terminology used for describing particular embodiments is not intended to be limiting of the invention. As used herein, the singular forms “a”, “an” and “the” are intended to include the plural forms as well, unless the context clearly indicates otherwise. The term “and/or” includes any and all combinations of one or more of the associated listed items. It will be understood that the terms “comprises” and/or “comprising” specify the presence of stated features but do not preclude the presence or addition of one or more other features. It will be further understood that when a particular step of a method is referred to as subsequent to another step, it can directly follow said other step or one or more intermediate steps may be carried out before carrying out the particular step, unless specified otherwise. Likewise, it will be understood that when a connection between structures or components is described, this connection may be established directly or through intermediate structures or components unless specified otherwise.

The present invention will be described with respect to particular embodiments and with reference to certain drawings, but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps.

Furthermore, the terms first, second, third and the like in the description and in the claims, are used for distinguishing between similar elements and not necessarily for describing a sequential or chronological order. It is to be understood that the terms so used are interchangeable under appropriate circumstances and that the embodiments of the invention described herein are capable of operation in other sequences than described or illustrated herein.

The terms “about” or “approximate” and the like are synonymous and are used to indicate that the value modified by the term has an understood range associated with it, where the range can be +20%, +15%, +10%, +5%, or +1%. The term “substantially” is used to indicate that a result (e.g., measurement value) is close to a targeted value, where close can mean, for example, the result is within 80% of the value, within 90% of the value, within 95% of the value, or within 99% of the value.

### Definitions

SPRING LOADED SUSPENSION BLOCK: A Spring loaded suspension block is a mechanical assembly containing a fixed part and a moving part between which springs are compressed. The spring loaded suspension block can also be provided by a pneumatic valve with compressed air or any resilient means which provide a similar effect. The spring tension or resilient means elasticity depends on the weight which is to be applied on the suspension block.

FRAME: A frame is a rigid framework that supports and positions the display modules and preferably comprises the power supply and data communication device of the display module. A frame may be configured to receive more than one display module.

FRAME ASSEMBLY: A frame assembly can comprise at least one frame but is generally a combination of at least two frames, which are fixed one with respect to the other for example with connection plates. The connection plates ensure the required alignment of one frame with respect to the other A frame assembly may for example comprise four frames arranged in a 2×2 matrix. Each frame may receive two display modules, in which case a frame assembly may comprise for example 8 display modules. The connection plates can provide a depth alignment at the edge between two frames better than 0.02 mm.

ROW OF FRAMES: horizontal combination of frame assemblies or individual frames which are installed and aligned together to channel profiles. The frame assemblies of a row of frames may be connected to each other with connection plates.

A DISPLAY WALL is usually composed of a plurality of individual display modules (or tiles) tiled together to form a larger display. The plurality of display modules can be operated together so that the overall display wall appears as a single, larger display. The front display surface can be formed from a plurality of individual light-emitting elements, such as LEDs, OLEDs, micro LEDs, etc., in which case the display modules are LED or OLED modules. Other types of displays can also be provided such as LCD displays, QDot displays, E-Ink displays, any type of reflective displays. A display wall can be controlled by at least one processor or display wall processor.

The DISPLAY MODULES of the display wall are configured to be installed in a frame.

VERTICAL refers to the Y-direction or up-down

HORIZONTAL refers to the X-direction or left-right

DEPTH direction refers to the Z-direction or in-out of XY plane

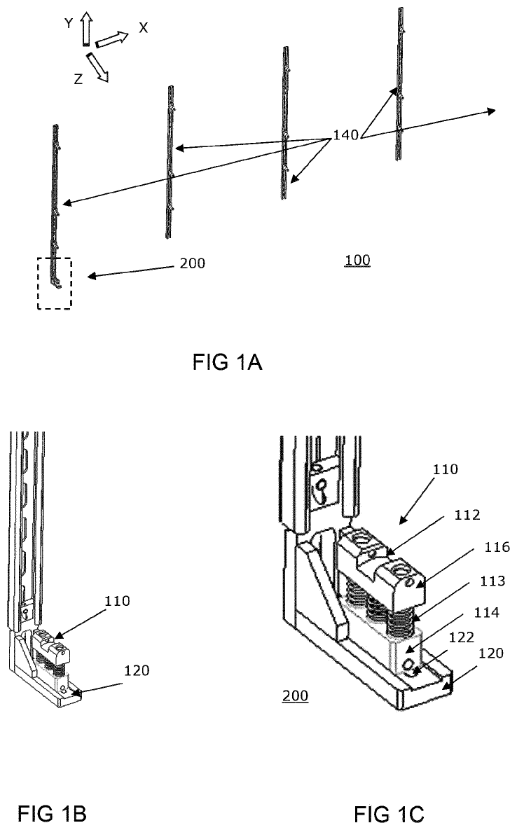

The X, Y and Z axis are illustrated in FIG. 1A.

Tilt angle is the angle formed by a frame around the horizontal X-axis in the Z-direction.

Precision bolts are preferably used for connecting parts together in an accurate way, as these parts combine fixation and positioning in the same part. In most cases this is a cheaper solution than having separate positioning and fixation. However, in some cases this is not possible or wanted e.g., in case of geometry, available space/accessibility, assembly requirements, strength . . . , then separate means for positioning and fixing can be used.

### DESCRIPTION

The installation of a display wall to a wall or steel structure requires the use of channel profiles on which a plurality of frames is mounted. The display modules are then fixed to the frames. The display modules should be aligned one with respect to the other, in the vertical direction (y), the horizontal direction (x) and in depth (z). Such an alignment of the display modules can only be achieved if the frames are aligned one with respect to the other within a pre-defined tolerance range. A depth misalignment, with respect to a reference plane, of one frame with respect to another can result in a different tilt angle of the frames one with respect to the other (tip-tilt angle) but can also result in a depth difference at the edges of the frames, such as a step.

Any misalignment will create visual artifacts which will disturb the image displayed on the display wall. The tolerance to be achieved generally depends on the pixel pitch of the tiled display wall. To achieve an alignment within a first tolerance range, the frames which are fixed to the channel profiles need to be aligned one with respect to the other. This alignment, within a first tolerance range, can only be achieved if the channel profiles and other fixation means are aligned within a second tolerance range, larger than the first tolerance range. The alignment accuracy, which is required, or the second tolerance range, can be approximately ±0.1° in tilt angle and/or a difference of 10 mm in depth (z) at the edges of the frames, 20 mm in the horizontal (x) and vertical (y) directions for the frames.

The different directions are illustrated in FIG. 1A.

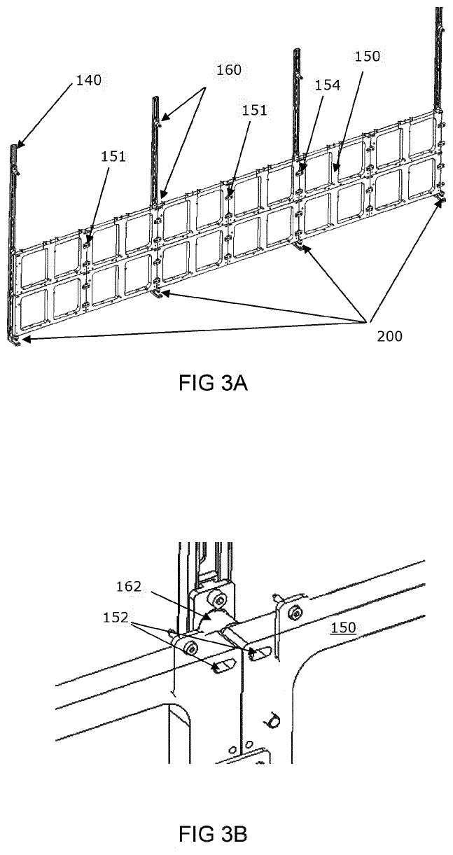

The frames 150 have positioning and mounting functionalities to receive and fix the display modules so the display modules can be combined in an accurate and seamless way. As shown in FIGS. 3A and 3B, a frame 150 has a front side 150F, a back side 150B, and an edge 150E disposed between the front side 150F and the back side 150B.

The present invention aims at creating and maintaining a good starting condition without impacting the installation time (no iterations), complexity (use of standard tools) and cost (no high level skills or accurate wall or site preparations needed) by providing alignment means for a support structure of a display wall.

FIG. 1A illustrates a plurality of channel profiles 140 of the support structure 100. These channel profiles can be provided by any type of Unistrut® profiles available on the market. The plurality of channel profiles 140 can be mounted to a wall or a steel structure for example. The installation of these channel profiles does not require any special accuracy or tooling, as in prior art installations, and these can be installed for example with a spirit level or a laser beam to ensure an accuracy within a second tolerance range, of 10 mm along the horizontal and vertical axis, and 10 mm in depth, for example. The flatness of the plane formed by these channel profiles can be within 10 mm, which is simple to achieve by the skilled person.

The channel profiles are generally installed vertically. The distance between two adjacent channel profiles can be a multiple number of frame assemblies, preferably one frame or two frames, for example if the frames are fixed to the channel profiles along their edges.

To increase the installation speed, it is preferred to install frame assemblies instead of frames on the support structure. A frame assembly is a combination of frames which are pre-aligned within the required specifications. A plurality of frames are fixed to one another with connection plates, ensuring a perfect alignment (a step smaller than 0.02 mm at the edges). In the example illustrated in FIG. 3A, a frame assembly is composed of 2 by 2 frames. The bigger the frame assemblies, the more difficult it is to install them, but the faster the installation process can be.

Before fixing the frames to the channel profiles, the frame assemblies are laid down on supporting means to support the load while fixing the frame assemblies to the support structure.

The supporting means are provided by spring suspension blocks. These are temporarily used when fitting the first row of frames. The spring loaded suspension blocks can be removed afterwards so the spring loaded suspension blocks do not protrude from the bottom of the screen.

FIGS. 1B and 1C show a close-up view of the supporting means 200.

The supporting means 200 comprise an active support provided by a spring loaded suspension block 110 for example. The spring loaded suspension block can be inserted in a receiver 120 configured to be attached or hooked to a bottom support inserted in the channel profile. The spring loaded suspension block and the receiver can also be made of one piece. The receiver 120 is preferably fixed to the bottom support mounted in a lower portion of the channel profile 140. As shown in FIGS. 1B and 1C, the receiver 120 is fixed to the bottom support in a direction extending away from the channel profile 140 in the Z-direction. The position of the spring loaded suspension block 110 can further be adjusted within the receiver 120 which comprises a slot 122 in which the spring loaded suspension block 110 can move.

FIG. 1C is a close-up view of the supporting means. The spring loaded suspension blocks 110 comprise a notch 112 configured to receive the edge of a frame. A plurality of springs 113 are fixed to a support 114, and a frame receiving portion 116 is fixed on the upper end of the springs 113. The notch can be in the frame receiving portion 116. The number of springs and/or the spring force depends on the weight of the frame which the spring loaded suspension block is to support during installation of the frame assemblies.

As shown FIG. 1C, the plurality of springs 113 are disposed to exert a restoring force along the Y-direction. The springs blocks have the advantage of supporting a weight very uniformly, i.e., the springs compress more if more weight lies on them. Providing a spring loaded suspension block at each channel profile results in a uniform supported base which forms a straight horizontal line. The vertical alignment (along Y) is thus easily achieved, and no additional tools are required.

The spring loaded suspension block is not limited to the use of steel wire springs but can also be provided by a pneumatic spring or other means providing the same functionality as a spring. In a pneumatic spring, the air pressure can be regulated, and thus also the height (Y-movement) of the frame.

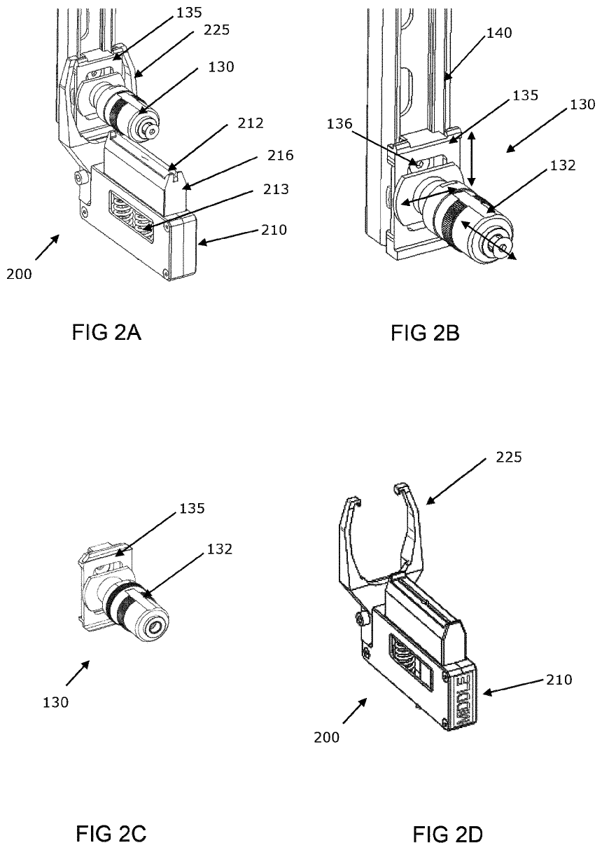

FIG. 2A shows another example of supporting means. In this example, the receiver and the spring loaded suspension block are provided by the same mechanical element 210. The spring loaded suspension block 210 comprises a plurality of springs 213. As shown FIGS. 2A and 2D, the plurality of springs 213 are disposed to exert a restoring force along the Y-direction. A frame receiving portion 216 is mounted on the spring loaded suspension block and comprises a notch 212.

After installation of the channel profiles, bottom supports comprising for example bottom fixation means 130 are installed on the channel profiles 140. The bottom supports are first aligned one with respect to the other using standard alignment means, such as a laser beam for example. The bottom supports are preferably aligned within the second tolerance range, which is preferably comprised in the range of [−10; 10] mm.

Top supports, for example provided by top fixation means 160 can also be installed in the channel profiles, approximately at a distance from the bottom supports equal to the distance between two frame mounting holes of a frame assembly. The top supports are preferably aligned within the second tolerance range, which is preferably comprised in the range of [−10; 10] mm.

The supporting means can then be fixed to the bottom supports. It is also possible to fix them directly to the wall or steel structure, however, it is easier to fix them to the bottom supports as it reduces the number of components to fix and align. Preferably, the supporting means are attached or hooked to the bottom support on the channel profile. As illustrated in FIG. 2A, the spring loaded suspension block 210 can be attached to the bottom support by means of a hooking mechanism 225. FIG. 2B is a close-up view of the bottom fixation means 130 mounted in the channel profile 140.

FIG. 2C illustrates the bottom supports provided by bottom fixation means 130.

FIG. 2D illustrates the supporting means 200, in which the hooking mechanism 225 to hook the supporting means to the bottom fixation means is clearly shown.

The bottom fixation means 130 may comprise a fixation frame 135 configured to slide in the channel profile until the desired position has been reached. The fixation frame 135 can thus be used to adjust the vertical position of the bottom support. A bolt can be used to fix this position. The position of the fixation frame can for example be adjusted using a laser and a reference point on the fixation frame 135.

The fixation frame 135 may further comprise a slot 136 in which the position of a bottom fixation point 132 can further be adjusted. The fixation point may be threaded such that untightening the fixation point within a nut arranged in the fixation frame may allow the fixation point to move along the horizontal and vertical axis within the fixation frame, as illustrated in FIG. 2B. The fixation point can also be used to adjust the depth, as described below. As shown in FIG. 2B, the bottom fixation means is configured to have the bottom fixation point 132 positioned to extend away from the channel profile 140 in the Z-direction.

Preferably, the hooking mechanism 225 of the supporting means is attached (or hangs) to the fixation frame 135. It can easily be removed after the installation as it is hangs to the fixation frame 135.

As illustrated in FIG. 3A, top supports comprising top fixation means 160 are installed in the channel profiles for example using a sliding mechanism. The top fixation means 160 can be used to fix an upper corner or an upper portion of a frame or of a frame assembly to the channel profile 140 while the frame assembly is supported by the supporting means. The top fixation means 160 can be identical or similar to the bottom fixation means 130.

The top fixation means 160 comprise top fixation points 162 which are configured to fix the frames to the channel profiles. As shown in FIG. 3B, the top fixation points 162 are attached to the frames 150 from the back side 150B. The depth of the frames with respect to the wall or a reference plane can be adjusted and fixed with the top fixation points 162. As shown in FIG. 3B, the top fixation points 162 is fixed to the back side 150B of the frame 150.

As illustrated in FIG. 3A, a first row of frames 1150 is laid on the spring loaded suspension blocks 110. The spring loaded suspension blocks ensure the support of the frames or the frame assemblies of the first row of frames one with respect to the other. The function of the spring loaded suspension block is also to compensate for the deviating position of the bottom supports while still supporting the frame in a uniform way.

This results in a stress-free framework avoiding deformations and enables the fixation of the frames or the frame assemblies of the first row of frames within a first tolerance range. The first tolerance range is preferably ±0.1 mm, even more preferably ±0.05 mm, and even more preferably ±0.01 mm along the x, y and z directions. The bottom supports are more roughly aligned on the channel profiles within a second tolerance range larger than the first tolerance range. The second tolerance range is preferably [−10; +10] mm along the x and y directions and [−5; +5] mm in the z direction.

In general, the first tolerance range depends on the pixel pitch of the display. In fact, the smaller the pixel pitch, the higher are the requirements on the alignment. To reduce visual artifacts within the tiled display, the first tolerance range is preferably smaller than 5% of the pixel pitch.

The frame assemblies can be attached one to the other at the edges, for example with connection plates 151. In FIG. 3A, the frame assemblies are composed of two by two frames, the frames are fixed to each other with connection plates 151. Each frame comprises two sub-frames for receiving each a display module, thus two display modules per frame.

The vertical position of the top fixation means 160 can then be adjusted to fix the first row of frames to the channel profiles. The frames are then also attached to top fixation points 162 of the top fixation means 160. An upper corner of a frame or of a frame assembly is attached to the top fixation point 162.

The frames may comprise horizontally slotted holes 152 in the corners in which the top fixation point 162 is fixed.

The top fixation points 162 are thus in the desired vertical position.

Preferably, one top fixation point 162 is provided per frame or per frame assembly. For example, the top fixation point can be mounted on the channel profiles in a location which corresponds substantially to an upper (top) corner of a frame assembly.

The top fixation points 162 also comprise means for adjusting the depth. The top fixation points can then be used to provide the desired depth (distance to the wall) to the frames. The depth adjustment can be obtained with a rotation of the top fixation point for example. Once the desired depth is reached, the top fixation point can be fixed for the depth alignment. The reference depth position can be provided with tape measure or with a laser beam.

The bottom fixation points 132 can then be used to adjust the orientation or tilt angle of the frames (or first row of frames) such that the frames are aligned with respect to a reference plane. The tilt angle of the frames can also be adjusted using a laser curtain or a spirit level. The spirit level will indicate a first spirit level for each frame assembly. It is important that the spirit level of each frame assembly in the first row is the same.

Once the desired tilt angle is achieved (or depth in the lower portion of the row of frames), the bottom fixation points 132 can be tightened to fix the position.

While fixing the fixation points 132, 162, the frames 150 preferably comprise horizontal slotted holes 152 to compensate for any horizontal deviation along X of the channel profile.

The roles of the top/bottom fixation points can be inverted when fixing the depth and adjusting the tilt angle.

If a mounting point is positioned slightly higher or lower due to drilling inaccuracies, incorrect drill hole marking, etc., the supporting means is capable of compensating for the deviating position while still supporting the frame in a uniform way.

This results in a stress-free framework avoiding deformations.

Once the first row of frames is properly installed and fixed to the channel profiles, the supporting means can be removed.

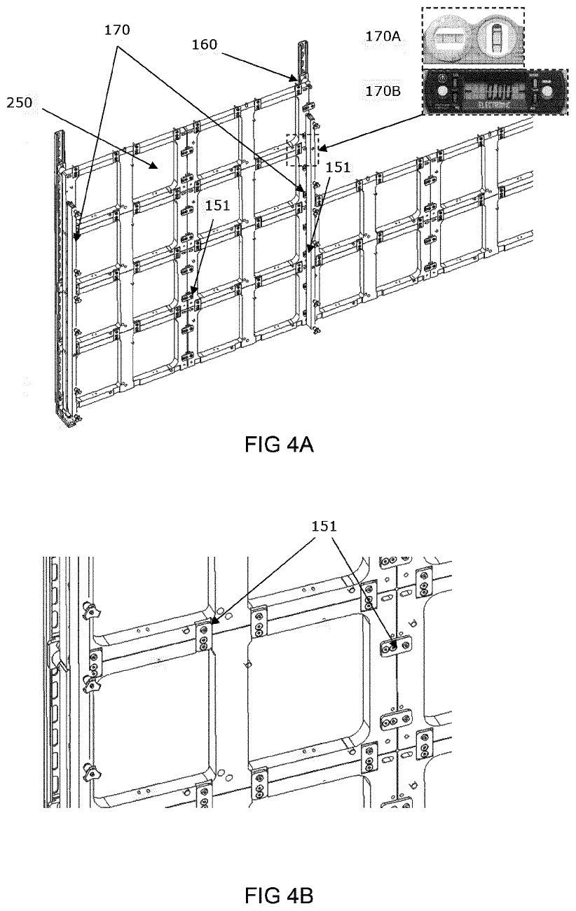

Once the first row of frames is installed and in the desired position, the second row of frames can be installed. The alignment of the second row of frames is performed with respect to the alignment of the first row of frames, which becomes a new reference plane for the second row. The installation of the second row of frames is illustrated in FIG. 4A.

Top supports for example provided by top fixation means 160 for the second row of frames are inserted in the channel profiles. A first frame assembly or frame of the second row of frames is provided on top of the first row of frames. Connection plates 151 at the edges between the first and second row can be fixed. The use of connection plates between the first and second row is illustrated for example in FIG. 4B.

Top fixation points 162 of the top fixation means 160 can be fixed in the slotted holes of the frames (for example the top left corner of a frame of a frame assembly) to fix the vertical and horizontal position of the frame assembly.

A ruler comprising a spirit level is then used for aligning the second row of frames with respect to the first row of frames. The spirit level of the ruler can be either an analogue (bubble) or a digital spirit level.

The ruler is preferably longer than the height of two rows of frames, such that the rigid ruler transfers the tilt angle of the first row of frames in a very direct way to the second row and acts as a reference to mount the frames in a straight line/plane with respect to the already installed row below (or above).

Preferably, the ruler comprises means to attach to the frames during alignment, while in contact with the surface of the frames. For example, pins can extrude from the frames and holes in the ruler can be configured to receive the pins during alignment.

In addition, the spirit level is used in such a way that the readings of the spirit level for the first row of frames is used as a reference for the second row of frames. The spirit level can thus be used first to measure the tilt angle of the first row, providing a first spirit level measurement.

During alignment of the second row of frames, the aim is to adjust the tilt angle of the frames such that the spirit level measurement of the second row of frames, the second spirit level measurement, matches the first spirit level measurement. This eliminates interpretation errors during the alignment procedure. Thus, only the indication changes of the sprit level (bubble moving, position change or digits change) are used to indicate whether a frame of the second row of frames is in line/plane or deviating from the reference line/plane of the first row.

The top fixation points 162 can be used to adjust the tilt angle of the frames in the second row to match the tilt angle of the frames in the first row.

The same installation sequence can be used for subsequent other rows. The installation is preferably performed from bottom to top with the previous row as a reference plane. Rows and columns can be added without limitations until finished.

However, it is also possible to start with an upper row and install a row beneath with respect to the upper row. This can be preferred for example when there is not sufficient room for providing the supporting means in the bottom of the display wall, if the display wall is mounted close to the floor for example.

FIG. 4A illustrates the use of the rigid ruler 170 comprising a spirit level 170A, 170B. The spirit level can be a digital or an analog spirit level. The rigid ruler is thus preferably longer than the sum of the height of the first and second rows.

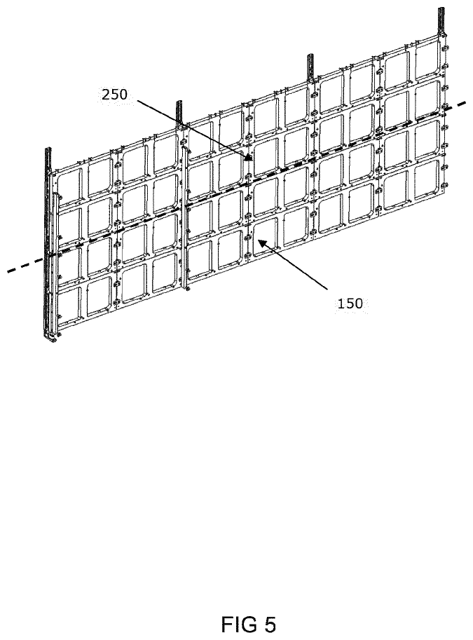

FIG. 5 illustrates the second row of frames 2150 aligned with respect to the first row of frames 1150.

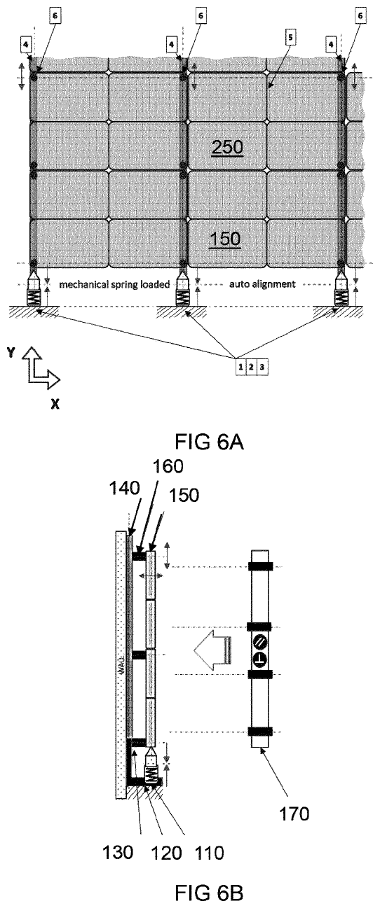

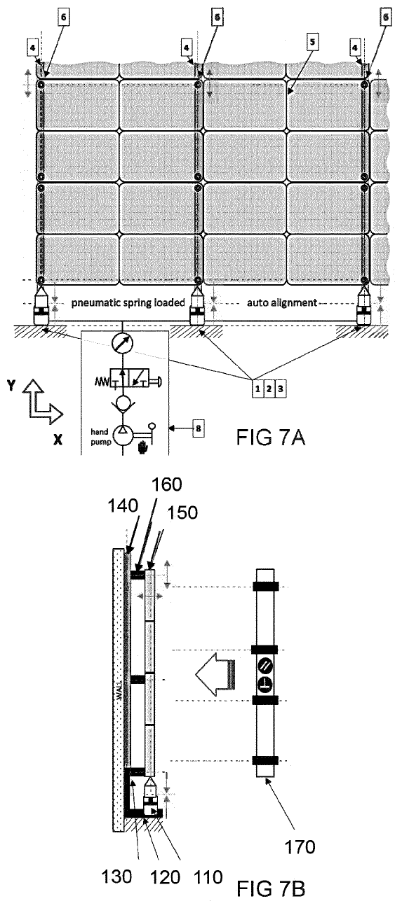

FIGS. 6A, 6B and 7A, 7B illustrate two examples of a support structure for a display wall aligned with the supporting means of the present invention.

In FIGS. 6A, 6B, the supporting means is provided by a spring loaded suspension block which is a mechanical wire spring. In FIGS. 7A, 7B, the supporting means is provided by a pneumatic valve with compressed air. As shown in FIGS. 6A and 7A, when the first row of frames in fixed on the corresponding channel profiles, the frames 150 may exert downward force to the supporting means and the supporting means exerts an upward force to the frames 150.

As illustrated in FIGS. 6A and 7A, the use of supporting means enables an auto-alignment of the first row of frames 1150 within the first tolerance range.

The top fixation means 160 and bottom fixation means 130 provide the fixations to the channel profiles 140 and the depth alignment is adjusted using the rigid ruler and spirit level 170.

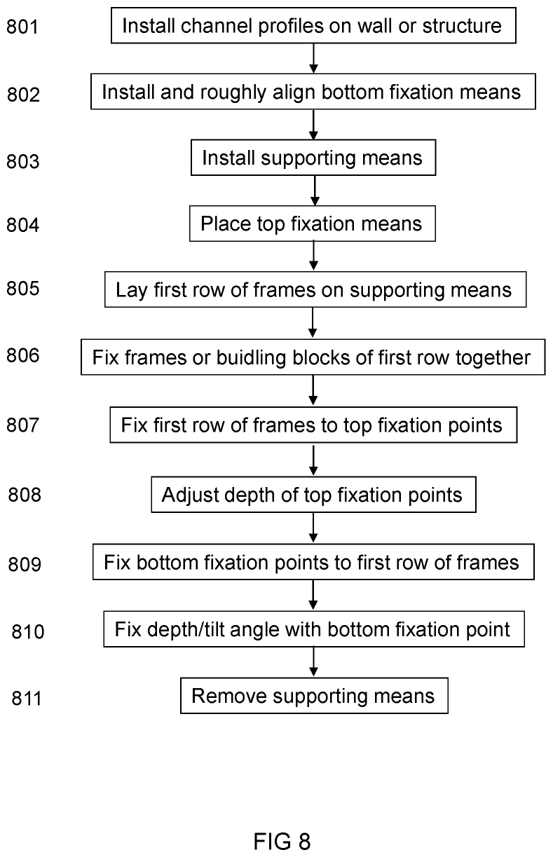

The present invention is also directed at a method of installing and aligning a tiled display module support structure. The different steps of the method with the installation sequence of the support structure and first row of frames are shown in the block diagram of FIG. 8.

The method for installing and aligning the tiled display module support structure can be performed as follows:

In a first step 801, channel profiles 140 are mounted against a wall, for example using bolts or screws which go into drilled holes. The channel profiles can also be installed on a steel structure. These channel profiles can be leveled out just roughly vertically with a standard spirit level, the horizontal spacing between adjacent channel profiles can be done with tape measure. The alignment precision is preferably within the second tolerance range, for example of ±5 mm along the horizontal and vertical axis, and ±10 mm along the depth.

In step 802, bottom fixation means 130 can then be mounted and aligned within the second tolerance range on the channel profiles. The bottom fixation means 130 can be aligned along the vertical axis for example with a horizontal laser beam, and thus within laser beam thickness, or ±5 mm along the vertical axis.

In step 803, the supporting means 200 can then be attached to the channel profiles. Preferably, the supporting means 200 are coupled to the bottom supports, for example provided by bottom fixation means 130.

In step 804, top supports, for example provided by top fixation means 160 can then be inserted into the channel profiles, for example with a sliding mechanism, and can be temporarily fixed in a position which roughly corresponds to the upper corner of the first row of frames which is to be installed.

In step 805, the first row of frames 1150 is laid down on the spring loaded suspension blocks 110 of the supporting means 200 by placing individual frame assemblies one by one. The individual frame assemblies are automatically aligned in Y direction because of the spring-loaded suspension blocks, as the springs will distribute the weight equally: the spring which is at highest point will be compressed most, until an equilibrium is reached with the other springs (compare it with a boxes spring principle). The reference height can be measured from a ground or reference marking, for example using a laser.

The individual frame assemblies of the first row of frames can then be fixed one to the other with connection plates, ensuring an alignment at the edges (step) of less than 0.02 mm. This is performed in step 806.

In step 807, the top fixation points of top support are fixed to the first row of frames, which is vertically and horizontally aligned. The vertical and horizontal position of the first row of frames is thereby fixed. The frames/frame assemblies may comprise a horizontally slotted hole in the upper corner, the slotted hole allowing to compensate for any misalignment of the channel profiles. A bolt can be used to fix the first row of frames to the top fixation point.

In step 808, the top fixation points are then used to adjust the depth (distance to the wall) of the frames. The depth can be adjusted for example by rotating the top fixation points. Once the desired depth has been reached, the depth can be fixed.

In step 809, while still being supported by the supporting means, the first row of frames is attached to the bottom fixation point of the bottom support; with for example a bolt, thereby fixing the vertical and horizontal alignment.

In step 810, the depth/tilt angle of the first row of frames can then be also fixed in the bottom support. For example, a laser curtain (and ruler) can be used as a reference to adjust the depth of the frames, or a spirit level can be used to adjust the tilt angle. The bottom fixation point of the bottom support is then adjusted to provide the required depth/tilt angle.

In step 811, the supporting means can be removed.

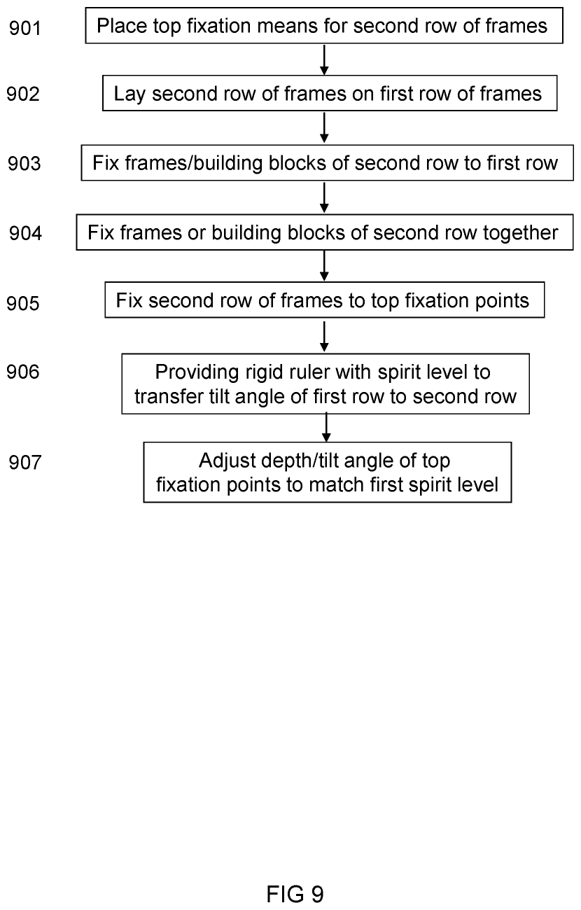

The installation of the second row of frames is depicted in FIG. 9. The installation of the second row of frames is performed using the first row of frames as a reference.

Therefore, the first step 901 is to place top fixation means in the channel profiles for the second row of frames.

In step 902, the frame assemblies of the second row of frames are laid on the first row of frames.

In step 903, the edges of the frames/frame assemblies of the second row are fixed to the edges of the frames of the first row preferably using connection plates.

In step 904, the edges of the frames/frame assemblies of the second row are fixed to one another preferably with connection plates.

In step 905, the second row of frames is fixed to the top fixation points of the fixation means. The second row of frames are positioned in horizontal and vertical direction.

In step 906, the depth or tilt angle of the second row of frames is adjusted with the top fixation points, using the first row of frames as a reference. This is achieved with the use of a rigid ruler, comprising a spirit level, analog or digital. The rigidity and length of the ruler transfers the tilt angle of the first row to the second row, by fixing the ruler vertically to the first and second row.

In step 907, using the spirit level, the tilt angle can be finely adjusted. The spirit level of the first row of frames is used as a reference, the first spirit level measurement. The second row is aligned with respect to the first row when the spirit level measurement of the second row matches the first spirit level measurement. The fine alignment is performed with the top fixation point which adjusts the depth, and thus the tilt angle of the second row of frame with respect to the first row of frames.

Additional rows can be mounted using the same installation sequence as for the second row. The subsequent rows are then aligned with respect to the previously installed row.

The order of the steps can be altered.

It is also possible to start with an upper or higher row and finish with the lowest row, for example.

When adjusting the depth or tilt angle, it is also possible to first fix the depth with the bottom fixation point and adjust the tilt angle with the top fixation point.

While the top supports are provided preferably in the top portion of a row of frames and the bottom supports are provided in the bottom portion, the placement of the top and bottom supports can also be inverted, i.e., the top supports can be provided in the bottom portion and the bottom supports in the top portion of the row of frames. In this case, the row of frames can be for example hooked to the supporting means which are in the upper portion of the row.

While the invention has been described hereinabove with reference to specific embodiments, this was done to clarify and not to limit the invention. The skilled person will appreciate that various modifications and different combinations of disclosed features are possible without departing from the scope of the invention.

1-40. (canceled)

41. A kit for aligning and fixing within a first tolerance range a support structure for a tiled display wall composed of a plurality of display modules wherein the support structure comprises:
a plurality of channel profiles configured to be arranged vertically and fixed to a wall or a structure,
a plurality of frame assemblies comprising at least one frame, wherein each frame is configured to receive at least one display module, and each frame has an edge, the plurality of frame assemblies are configured to be arranged in a first row of frames,
wherein the kit comprises
a plurality of bottom supports configured to be aligned within a second tolerance range larger than the first tolerance range, and configured to be mounted on the channel profiles,
a plurality of top supports configured to be mounted on the channel profiles, and
supporting means comprising a plurality of spring loaded suspension blocks configured to be attached to the bottom supports, such that, when the frame assemblies are laid on the supporting means, the supporting means receives the edges of the first row of frames and supports the frame assemblies while aligning and fixing the frame assemblies, within the first tolerance range, to the top supports.

42. The kit according to claim 41, further comprising top fixation means provided in the top supports, the top fixation means further comprising means to adjust at least one of the horizontal, the vertical and the depth position of the upper portion of the first row of frames with respect to a reference plane, or
further comprising bottom fixation means provided in the bottom supports, the bottom fixation means further comprising means to adjust at least one of the horizontal, the vertical and the depth position of the lower portion of the first row of frames with respect to a reference plane.

43. The kit according to claim 42, wherein the bottom fixation means comprise a bottom fixation point for fixing the bottom portion of the first row of frames to the channel profile.

44. The kit according to claim 43, wherein the bottom fixation point is provided in a fixation frame comprising a slot, wherein at least one of the position of the bottom fixation point is configured to be adjusted within the frame for fixing the horizontal and/or vertical position of the first row of frames and/or wherein the depth of the fixation point is configured to be adjusted for fixing the depth of the first row of frames.

45. The kit according to claim 41, wherein the supporting means are configured to be removable after installation of the support structure.

46. The kit according to claim 41, wherein the supporting means are coupled to the bottom supports, wherein the coupling mechanism is a hooking mechanism.

47. The kit according to claim 42, wherein the top fixation means comprises a top fixation point for fixing the upper portion of the first row of frames to the channel profiles, and/or wherein the top fixation point is provided in a fixation frame comprising a slot, wherein the position of the top fixation point is configured to be adjusted within the frame, and/or wherein the top fixation point is further configured to adjust the depth of the upper portion of the row of frames.

48. The kit according to claim 41, further comprising a rigid ruler comprising a spirit level, the rigid ruler being configured to mechanically transfer the orientation of an aligned upper or lower row of frames, and the spirit level being configured to provide a spirit level reference of an aligned upper or lower row of frames to align the row of frames with respect to the aligned upper or lower row of frames, and/or wherein the spirit level is an analog or digital spirit level.

49. A support structure for a tiled display wall, the support structure comprising:
a plurality of channel profiles configured to be arranged vertically and fixed to a wall or a structure,
a plurality of frame assemblies comprising at least one frame, wherein each frame is configured to receive at least one display module, the plurality of frame assemblies are configured to be arranged in a row of frames,
and further comprising the kit according to claim 41.

50. The support structure according to claim 49, wherein the frames are provided with horizontally slotted holes in the upper and/or lower portions for fixing the frames into the top and/or bottom supports, and/or wherein the slotted holes are provided in the corners of the frames.

51. The support structure according to claim 50, wherein individual frame assemblies are fixed to each other with connection plates provided along the edges.

52. A method for aligning and fixing within a first tolerance range a support structure for a tiled display wall, the method comprising the steps of:
installing a plurality of channel profiles vertically on a wall or structure, providing a plurality of bottom supports aligned within a second tolerance range larger than the first tolerance range, in the channel profiles,
providing a plurality of top supports in the channel profiles,
attaching supporting means comprising a plurality of spring loaded suspension blocks to the bottom supports,
providing a plurality of frame assemblies to be arranged in a first row of frames, each frame having an edge and being configured to receive at least one display module, laying the frame assemblies on the supporting means, such that the supporting means receives the edges of the first row of frames and supports the frame assemblies,
fixing and aligning, within the first tolerance range, the frame assemblies to the top supports.

53. The method according to claim 52, further comprising the step of providing additional frame assemblies to compose the first row of frames and of connecting the frame assemblies together at their edges, preferably with connection plates.

54. The method according to claim 53, wherein the top supports further comprise top fixation means, the top fixation means further comprising means to adjust at least one of the horizontal, the vertical and the depth position of the upper portion of the first row of frames with respect to a reference plane and wherein the method further comprises the step of fixing the upper portion of the frame assemblies to the top fixation means, and/or
wherein the bottom supports further comprise bottom fixation points, the bottom fixation points further comprising means to adjust at least one of the horizontal, the vertical and the depth position of the bottom portion of the first row of frames with respect to a reference plane and comprising the step of fixing the bottom portion of the frame assemblies to the bottom fixation points.

55. The method according to claim 54, further comprising the step of adjusting the depth of the upper portion of the first row of frames with the top fixation means and/or wherein the step of adjusting the depth is performed with a laser beam, or a laser curtain, or a laser grid.

56. The method according to claim 54, further comprising the step of adjusting the depth of the bottom portion of the first row of frames with the bottom fixation points.

57. The method according to claim 52, further comprising the step of removing the supporting means from the bottom supports.

58. The method according to claim 52, wherein the step of providing a plurality of bottom and/or top supports aligned within a second tolerance range larger than the first tolerance range, in the channel profiles, is performed with at least one of a laser beam, a laser curtain, a laser grid, or a spirit level.

59. The method according to claim 52, further comprising the step of providing a second row of frames on or below the first row of frames and/or further comprising the step of providing the second row of frames is performed by providing additional frame assemblies to compose the second row of frames and of connecting the frame assemblies together at their edges, preferably with connection plates.

60. The method according to claim 59, further comprising the step of providing a plurality of top supports for the second row of frames, in the channel profiles and/or wherein the step of adjusting the depth is performed by mechanically transferring the orientation of the aligned upper or lower row of frames to the second row of frames with a rigid ruler.

61. The method according to claim 60, wherein said rigid ruler further comprises a spirit level, and further comprising the step of adjusting the orientation of the second row of frames by adjusting the readings of the spirit level to the readings of the spirit level for the aligned upper or lower row of frames.
